(19) United States
(12) Patent Application Publication
(10) Pub. No.: US 2025/0277882 A1
(43) Pub. Date: Sep. 4, 2025

(54) Fully automated pipeline for the robust segmentation of vascular and perivascular spaces (PVS) on brain Magnetic Resonance Imaging (MRI) data

(71) Applicant: The Board of Trustees of the Leland Stanford Junior University, Stanford, CA (US)

(72) Inventor: Giuseppe Barisano, Palo Alto, CA (US)

(21) Appl. No.: 19/067,341

(22) Filed: Feb. 28, 2025

Related U.S. Application Data
(60) Provisional application No. 63/559,572, filed on Feb. 29, 2024.

(51) Int. Cl. G01R 33/56

(52) U.S. Cl. CPC G01R 33/5608; G01R 33/5602

(57) ABSTRACT

A method for magnetic resonance imaging including segmentation of vascular and perivascular compartments on MRI data includes a) performing an MRI scan to produce a three-dimensional T1-weighted image; b) generating from the three-dimensional T1-weighted image a white matter mask; c) generating from the white matter mask a vesselness map using a multiscale vessel enhancement filtering technique; d) automatically estimating a threshold on the vesselness map to define vascular structures, where the threshold is a vesselness value corresponding to a predetermined percentile (preferably 85%) of the total number of non-zero voxels; and e) automatically generating a segmentation mask of vascular and perivascular structures using the estimated threshold to retain and binarize voxels with vesselness value above the estimated threshold.

### CROSS-REFERENCE TO RELATED APPLICATIONS

This application claims priority from U.S. Provisional Patent Application 63/559,572 filed Feb. 29, 2024, which is incorporated herein by reference.

### STATEMENT OF FEDERALLY SPONSORED RESEARCH

This invention was made with Government support under contract CA261717 awarded by the National Institutes of Health, and under contract CA216054 awarded by the National Institutes of Health. The Government has certain rights in the invention.

### FIELD OF THE INVENTION

The present invention relates generally to magnetic resonance imaging (MRI). More specifically, it relates to methods for segmentation of vascular and perivascular compartments on MRI data.

### BACKGROUND OF THE INVENTION

In vivo evaluation of cerebral small vessel disease relies on magnetic resonance imaging (MRI) and includes different signs of brain parenchymal damage (e.g., white matter lesions, lacunes, subcortical infarcts, cerebral microbleeds, and enlargement of perivascular spaces). These MRI signs are traditionally assessed with visual qualitative scales which have lower sensitivity compared with quantitative measures, require specific MRI sequences, or are labour intensive to process. Using the perivascular spaces (PVS) as detected on MRI to non-invasively evaluate cerebral small vessel health requires only an unenhanced 3-dimensional T1-weighted images, a nearly universal brain MRI sequence. Current techniques of PVS estimation, however, suffer from user-dependency and weak or unknown robustness and inter-scanner reproducibility. These limitations prevent generalised, widespread use in the hospital, clinical trials, and multi-centre longitudinal studies.

Currently it is very difficult to reliably segment vascular and perivascular spaces on brain MRI acquired non-invasively. There is no fully automated method and no computational approach that has shown consistency across different MRI scanner and on test-retest experiments (i.e., same person scanned twice on the same scanner). Existing methods for the segmentation and/or quantification of vascular and perivascular structural properties are not fully-automated, as they include steps requiring a human intervention (e.g., manual selection of thresholds for filtering techniques) and/or human-based training datasets for artificial intelligence algorithms. Importantly, the inter-scanner reproducibility of these methods is weak.

Current methods for vascular segmentation are scanner-dependent, user-dependent, and not suitable in longitudinal analysis. There is thus a need for reliable, accurate, and non-invasive measurements of vascular compartments and structures.

### SUMMARY OF THE INVENTION

Herein is disclosed a method that is able to segment and robustly quantify vascular and perivascular spaces (PVS) in the brain from any 3-dimensional T1-weighted MRI image in a fully automated way, and the obtained PVS metrics show excellent inter-scanner reproducibility and test-retest repeatability. Additionally, this method is able to automatically and robustly segment PVS on longitudinal MRI data. This method can assess in vivo the structural properties of the cerebral microvessels.

The method is fully automated (i.e., it requires no user intervention or input), and is robust in longitudinal assessment of vascular and perivascular compartments in the brain. These characteristics are critical for an accurate and reliable assessment of the brain vasculature in vivo.

It is demonstrated that the metrics obtained with this method are able to identify non-demented individuals at increased risk of developing dementia and brain atrophy. This is relevant not only for clinical purposes, but also in clinical trials for cognitive impairment and dementia, because it allows to enrich the trials with individuals more likely to experience cognitive decline, and therefore reducing the minimal number of subjects required to be enrolled in the trial, with a significant impact on the costs and efficiency of the trial. Moreover, the vascular markers obtained with the segmentation performed by this method will open new opportunities for clinical trials that are interested in assessing an effect of a treatment on the blood vessels of the brain parenchyma in vivo.

The method has clinical application for predicting incident dementia and brain atrophy in non-demented patients and for screening subjects in clinical trials. Companies could use this method to provide services for researchers, individual patients, or any size of preclinical and clinical trials. These provided services include the evaluation of biomarkers that can non-invasively assess the brain vasculature, providing clinicians and scientists new means for early detection of brain dysfunction and enhanced characterization of neurological disorders.

In one aspect, the invention provides a method for magnetic resonance imaging including segmentation of vascular and perivascular compartments on MRI data. The method includes a) performing an MRI scan to produce a three-dimensional T1-weighted image; b) generating from the three-dimensional T1-weighted image a white matter mask; c) generating from the white matter mask a vesselness map using a multiscale vessel enhancement filtering technique; d) automatically estimating a threshold on the vesselness map to define vascular structures, wherein the threshold is a vesselness value corresponding to a predetermined percentile of the total number of non-zero voxels; and e) automatically generating a segmentation mask of vascular and perivascular structures by i) using the estimated threshold to retain and binarize voxels with vesselness value above the estimated threshold, ii) using anatomical landmarks to exclude white matter areas where false positive vessel-like structures are commonly found, and iii) using morphological features of the retained voxels to further exclude voxels that represent background noise and are not consistent with vascular and perivascular structures. The predetermined percentile may be in the range from 50 to 99, preferably in the range from 75 to 90, more preferably in the range from 84 to 86, and most preferably equal to 85. Step (b) may be performed, for example, using a FreeSurfer recon-all pipeline. Step (c) may be performed, for example, by applying the Frangi filter with default parameters.

The method may also include generating from the three-dimensional T1-weighted image a basal ganglia mask. The vesselness map in this case may be generated from the white matter mask and the basal ganglia mask. In this case, the anatomical landmarks may be used also to exclude basal ganglia areas where false positive vessel-like structures are commonly found.

### BRIEF DESCRIPTION OF THE DRAWINGS

FIG. 1 is a processing pipeline providing an overview of a method for MRI, according to an embodiment of the invention.

FIG. 2A is a graph of cumulative proportion of voxels vs. log of vesselness value from the Frangi filter for three different scanners, demonstrating that prior approaches lack inter-scanner reproducibility.

FIG. 2B shows images of vessel-like masks from three different scanners, demonstrating how different scanners lead to different amounts of identified voxels.

FIG. 2C is a graph of cumulative proportion of voxels vs. log of vesselness value, illustrating different thresholds for images produced by different scanners, according to an embodiment of the invention.

FIG. 2D shows images of vessel-like masks from three different scanners, demonstrating how different scanners lead to consistent amounts of identified voxels, according to an embodiment of the invention.

### DETAILED DESCRIPTION OF THE INVENTION

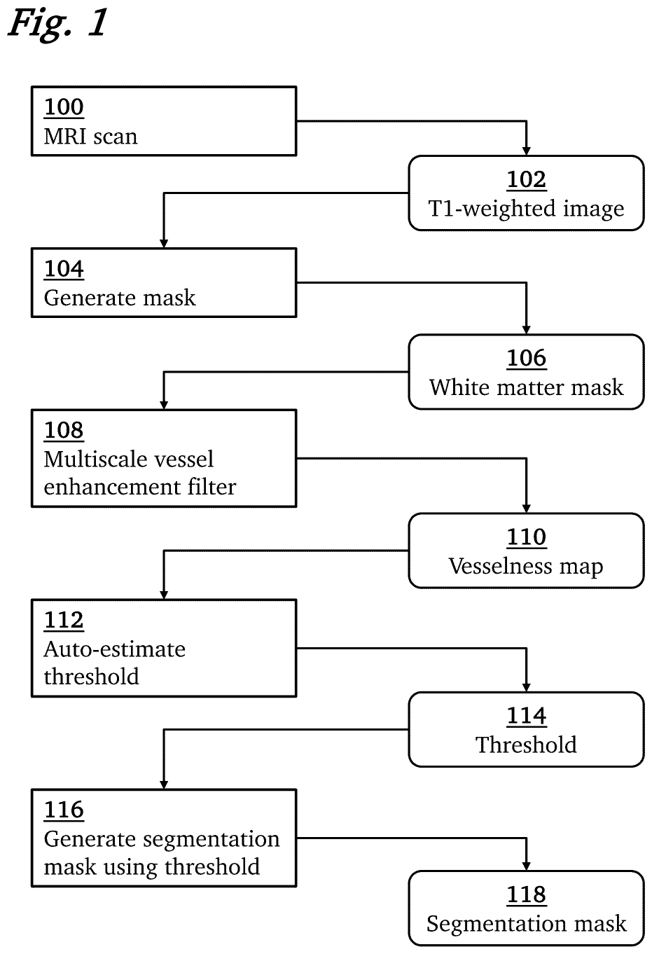

FIG. 1 is a processing pipeline providing an overview of a method for MRI including automatic segmentation of vascular and perivascular structures, according to an embodiment of the invention. In step 100, an MRI scan is performed by an MRI scanner to produce a three-dimensional T1-weighted image 102. The subsequent steps may be performed by the scanner or other processor external to the scanner.

In step 104 a white matter mask 106 is generated from the three-dimensional T1-weighted image 102. This may be performed with any of various standard approaches such as the FreeSurfer recon-all pipeline.

In step 108 a vesselness map 110 is generated from the white matter mask 106 using a multiscale vessel enhancement filtering technique. This may be performed by applying a Frangi filter with default parameters on the processed T1-weighted image to generate the vesselness map.

In step 112 a threshold 114 on the vesselness map 110 is automatically estimated to define vascular structures. The threshold 114 is a vesselness value corresponding to a predetermined percentile of the total number of non-zero voxels. In prior approaches, at this step a user instead would be required to manually identify and set up a threshold that is then used to define and segment the vascular and perivascular structures. However, this manual approach leads to results that lack robustness and inter-scanner reproducibility because of the heterogeneity of the signals on T1-weighted images. This is a significant burden as it does not allow to obtain reliable vascular measures and prevents its wide implementation in the clinics, in research studies, and in clinical trials. The present method is completely automated and overcomes this obstacle. The threshold is automatically estimated and used for a segmentation of the vascular and perivascular structures to obtain vascular measures that are robust, reliable, and consistent across any type of T1-weighted image.

In step 116 a segmentation mask 118 of vascular and perivascular structures is automatically generated by the following sub-steps: i) using the estimated threshold to retain and binarize voxels with vesselness value above the estimated threshold, ii) using anatomical landmarks to exclude white matter areas where false positive vessel-like structures are commonly found, and iii) using morphological features of the retained voxels to further exclude voxels that represent background noise and are not consistent with vascular and perivascular structures. Regarding the anatomical landmarks, FreeSurfer and other software are able to create parcellations of the brain, and this allows for example to identify and label areas of the white matter according to the neuroanatomical atlas (for example it identifies the white matter of the frontal lobe, of the occipital lobe, etc.). These labels are used to identify areas of the white matter to be excluded, because some white matter areas are either known to have no PVS (e.g., the corpus callosum) or represent pathological white matter where PVS are difficult to assess (e.g., the white matter lesions). Regarding the morphological features, these correspond to the PVS cluster size. As described earlier, we basically exclude all PVS clusters with in-plane size of less than two voxels, because these are in most cases noise and not true PVS as they do not have the linear shape typical of PVS.

This fully-automated algorithm segments PVS from clinical T1-weighted MRI images and provides robust estimates of PVS count and size with excellent inter-scanner reproducibility and test-retest repeatability (intraclass correlation coefficients >0.8). The simplicity and efficiency of our technique in robustly and automatically assessing PVS on clinical MRI facilitate its implementation in hospitals, clinical trials, and even retrospectively for MRI data already acquired.

This fully automated approach robustly estimates PVS in the white matter (WM-PVS) and basal ganglia (BG-PVS), and it accomplishes this using as input only unenhanced 3D T1-weighted images.

MRI data were acquired with a variety of 1.5- and 3-Tesla MRI scanners and sequences. All T1-weighted images were processed using the recon-all module of the freely available FreeSurfer software package (v7.4), which resampled all the images to 1 mm isotropic resolution and performed an atlas-based brain parcellation. The longitudinal processing scheme was used for estimating brain atrophy (grey and white matter volumes, and cortical thickness) longitudinally. For validation of our technique, white matter lesions (WML) were segmented with a previously validated approach on T1-weighted images. We classified as periventricular WML the clusters of WML adjacent to the lateral ventricles; the remaining clusters of WML were classified as deep WML.

PVS were segmented using our approach that advances previous techniques by being fully-automated and showing excellent inter-scanner reproducibility. We employed the filter developed by Frangi et al. to enhance tubular, vessel-like structures on T1-weighted images and generate “vesselness maps” as previously described. Briefly, the Frangi filter enhances tubular, vessel-like structures on a grayscale image and assigns a “vesselness” value to each voxel [symbol] (s) from eigenvectors λ of the Hessian matrix [symbol] of the image as:

$$𝒱 ( s ) = \{ \begin{matrix}0 if {λ}_{2} > 0 or {λ}_{3} > 0 , \\ ( 1 - exp ( - \frac{{ℛ}_{A}^{2}}{2 {α}^{2}} ) ) exp ( - \frac{{ℛ}_{B}^{2}}{2 {β}^{2}} ) ( 1 - exp ( - \frac{{𝒮}^{2}}{2 {c}^{2}} ) )\end{matrix}$$

$$where$$

$${ℛ}_{A} = \frac{\vert {λ}_{1} \vert}{\vert {λ}_{2} \vert} , {ℛ}_{B} = \frac{\vert {λ}_{1} \vert}{\sqrt{\vert {λ}_{2} {λ}_{3} \vert}} , S = ‖ ℋ ‖ .$$

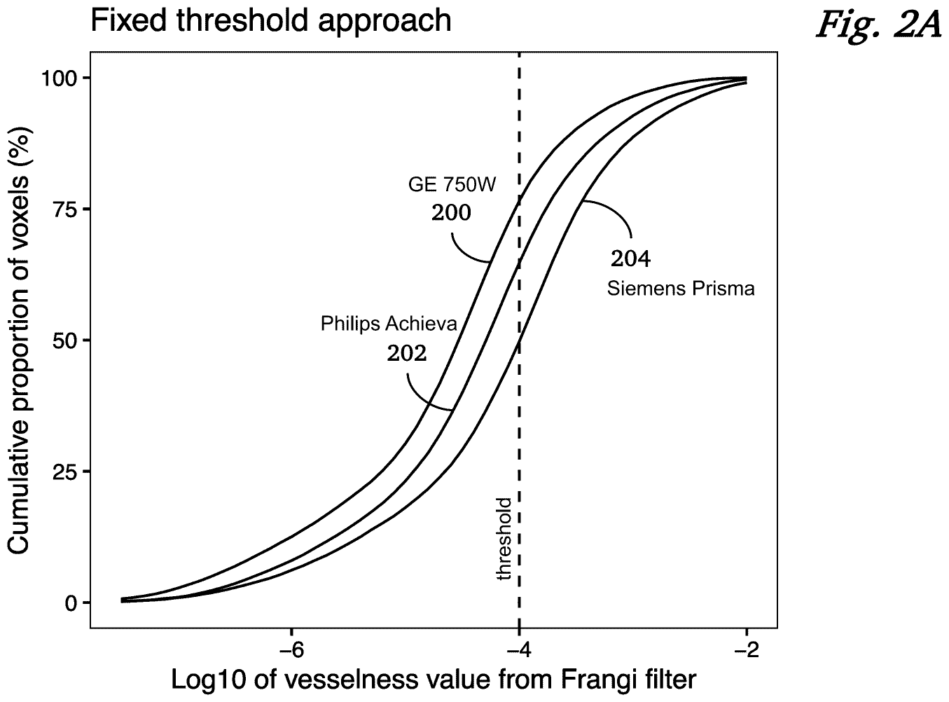

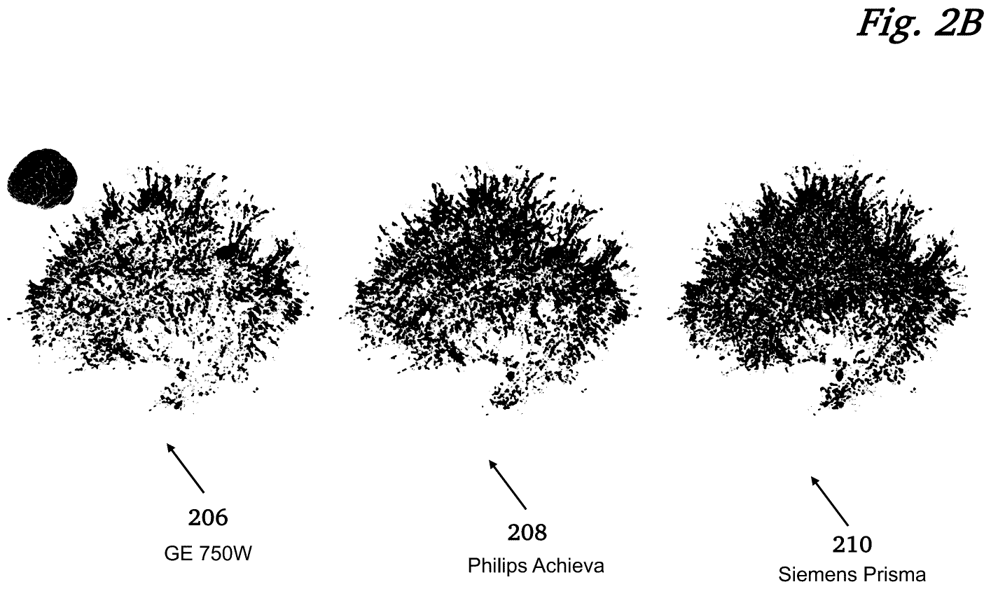

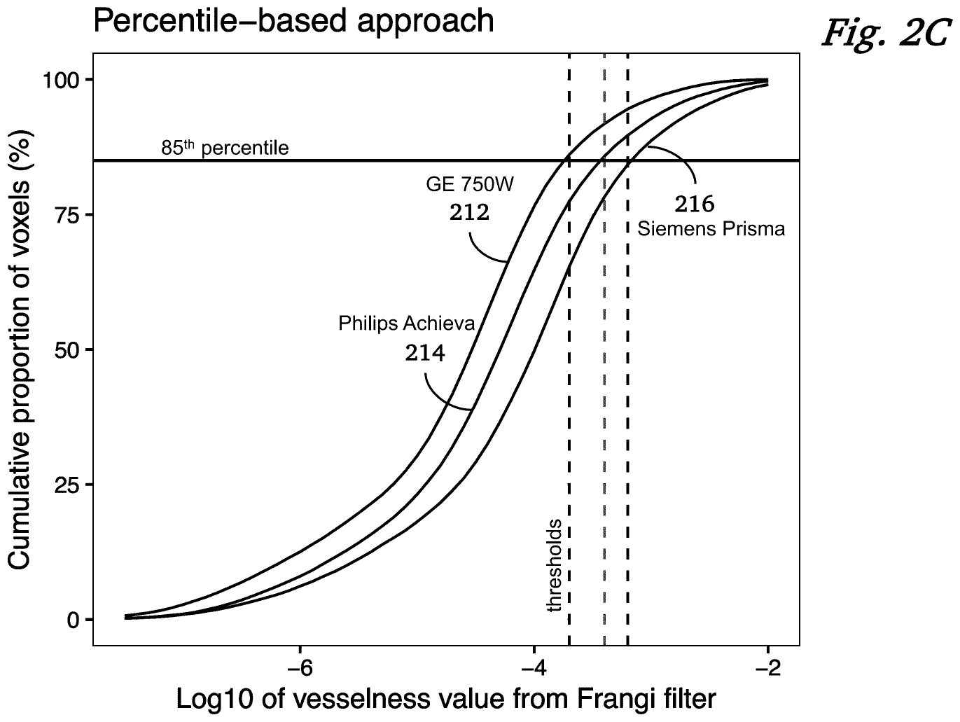

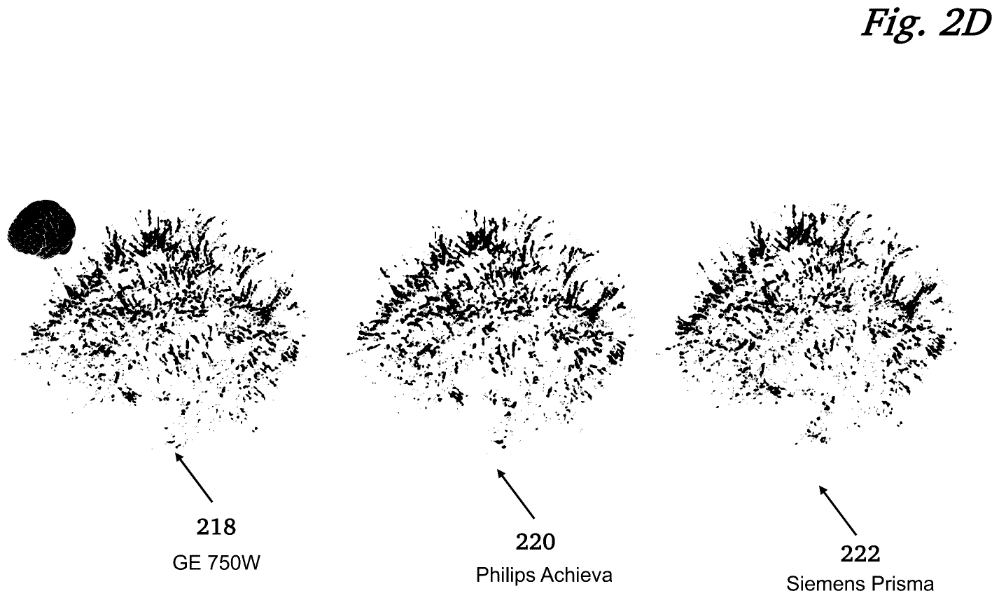

We previously implemented and validated this filter for the segmentation of MRI-visible vascular and perivascular spaces on T1-weighted images using the default, recommended parameters of α=0.5, β=0.5, and c set to half the value of the maximum Hessian norm. That prior approach, however, requires the user to identify a threshold on the vessel map generated by the filter to define the vessel-like structures: values above that threshold (i.e., with high “vesselness” values) are considered vascular and perivascular spaces, and values below are excluded. However, since the scale of the “vesselness” values generated by the filter differs from image to image (FIG. 2A) depending on the signal intensity values of the input image, and since the signal intensity values on T1-weighted images are represented in arbitrary units which may vary depending on the MRI machine and its calibration, this approach lacks inter-scanner reproducibility (FIG. 2b) and is potentially biased even in longitudinal studies. To overcome this issue, we developed and validated an approach for the segmentation of PVS applicable to virtually any type of T1-weighted image.

FIGS. 2A-2D compare the original approach of segmentation and the approach of the present invention. FIG. 2A is a graph of cumulative proportion of voxels vs. log of vesselness value from the Frangi filter for three different scanners: GE 750 W 200, Philips Activa 202, and Siemens Prisma 204. The original approach requires one to set a single threshold (e.g., the vertical dashed line in the figure), and to use this threshold to segment vessel-like structures. However, this approach lacks inter-scanner reproducibility, because the scale of the vesselness maps depends on the signal intensity of the input image, which may differ among MRI scanners and protocols. In fact, in this example the threshold would lead to very different number of segmented voxels, as shown in FIG. 2B where images 206, 208, 210 of vessel-like masks from three different scanners have significantly different amounts of identified voxels. Vessel-like masks from Siemens scanner will have approximately 12.5 and 25% more voxels than those from Philips and GE scanners, respectively.

In the present approach, we set specific thresholds to the individual images. FIG. 2C is a graph of cumulative proportion of voxels vs. log of vesselness value, illustrating different thresholds for images produced by different scanners: GE 750 W 212, Philips Activa 214, and Siemens Prisma 216. The three vertical dashed lines are different thresholds based on the value of the voxel corresponding to the 85^{th} percentile (black horizontal solid line) of the total number of non-zero voxels of the vesselness map. This approach leads to consistent PVS masks and robust metrics derived from the PVS masks, while preserving inter-individual differences and accuracy, as shown in FIG. 2D where images of vessel-like masks from three different scanners have consistent amounts of identified voxels. FIGS. 2B, 2D report the 3D representations of the PVS segmentation masks of the same participant obtained with 3 different MRI scanners with fixed threshold approach and the present percentile-based approach, respectively.

Our approach is based on the discovery that the total number of voxels with non-zero vesselness value obtained from the Frangi filter applied on T1-weighted images is consistent across brain images of the same participant acquired with different MRI scanners (inter-scanner and inter-field-strength reproducibility), is consistent across brain images of the same participant acquired on two different MRI sessions with the same MRI scanner and protocol (test-retest repeatability), and is significantly associated with age, sex, and body mass index as previously described for PVS, supporting the reliability of the PVS segmentation.

In our approach, the value of the voxel corresponding to a single, specific percentile of the total number of voxels with non-zero “vesselness” values is used as a threshold for consistently and robustly segmenting MRI-visible vessel-like structures across different types of T1-weighted images (FIGS. 2c and d). We identified this percentile to be 85% in the white matter, based on the average ratio between the number of voxels that we previously segmented as vascular and perivascular spaces in the Human Connectome Project dataset and the corresponding total number of voxels with non-zero vesselness value.

In each individual vesselness map generated by the Frangi filter, the vesselness value corresponding to the 85th percentile of the total number of non-zero voxels was automatically computed: the voxels with vesselness value above this threshold were retained and binarized to make the PVS mask, whereas those below or equal to the threshold were excluded. Although 85% is the ideal value, the method still has utility for thresholds in the range 84% to 86%, 75% to 90%, and even 50% to 99%.

To improve the specificity of the PVS segmentation, the Frangi filter was applied on FreeSurfer's white matter mask with the following modifications: the voxels labeled as corpus callosum by FreeSurfer were excluded; periventricular areas were excluded by subtracting FreeSurfer's lateral ventricle binary mask enlarged by 3 units from the white matter binary mask; WML were also excluded. Finally, we used MATLAB's regionprops3 function with the default 26-connected neighborhood definition to compute PVS count and mean diameter across all PVS clusters with in-plane size of at least 2 voxels detected in the modified white matter mask of each image.

Accuracy of the PVS segmentation was assessed via visual inspection and quantified with the Dice similarity coefficient using as a reference the PVS masks obtained with an established and previously validated technique applied on the HCP dataset. The Dice similarity coefficient ranges from 0, indicating no spatial overlap between two sets of binary segmentation masks, to 1, indicating complete overlap.

The robustness of the PVS metrics assessed in our study (i.e., PVS count and PVS mean diameter) across different MRI scanners (inter-scanner and inter-field-strength reproducibility) and sessions (test-retest repeatability) was assessed with the intraclass correlation coefficients, ranging from 0 to 1, where a higher value indicates higher agreement between the compared modalities. Similar evaluations were also performed for WML metrics.

The spatial overlap between the PVS masks obtained with our fully-automated approach and those obtained with a previously validated semi-automated technique was very high (Dice similarity coefficient: 0.95±0.0001) and the numbers of PVS voxels identified with the two methods were strongly correlated. Consistently, PVS measured with our method also showed a strong positive association with age, male sex, and body mass index in the Human Connectome Project dataset, replicating results previously published with the validated semi-automated techniques. These data support the reliability and accuracy of our PVS masks. While previous methods are user-dependent (i.e., the user needs to identify a threshold for each type of T1-weighted image) and lack inter-scanner reproducibility of PVS markers (FIG. 2a-b), our technique is able to provide measurements of PVS count and diameter in a fully automated and robust way (FIG. 2c-d). Indeed, both metrics showed excellent intraclass correlation coefficients (≥0.9 for WM-PVS and ≥0.8 for BG-PVS) for inter-scanner reproducibility, inter-field-strength reproducibility, and test-retest repeatability. We also observed a strong correlation between the numbers of PVS voxels independently identified by our algorithm on the T1-and T2-weighted images, with an average of 87.3+5.7% of PVS voxels detected on T1-weighted images that overlapped with PVS voxels on T2-weighted images. Overall, these data show that our method can accurately segment PVS on T1-weighted images and that T1-weighted images are suitable to reliably assess PVS morphological metrics and inter-participant differences. In contrast with previous methods, our new approach for PVS segmentation is fully automated, requires only T1-weighted images, and provides robust metrics across different scanners and protocols.

Excellent results were also obtained for WML. WML voxels segmented on T1-weighted images were strongly correlated with WML voxels segmented on FLAIR, with an average of 83.0+0.4% of WML voxels detected on T1-weighted images that overlapped with WML voxels on FLAIR. Moreover, WML volume showed excellent intraclass correlation coefficients (>0.9 for P-WML and >0.8 for D-WML) for inter-scanner reproducibility, inter-field-strength reproducibility, and test-retest repeatability.

In summary, herein we have disclosed a fully automated, robust technique to obtain unbiased, quantitative metrics of PVS from clinical brain MRI T1-weighted images. We demonstrated that our method provides accurate segmentations with high inter-scanner reproducibility. These characteristics allowed us to apply this technique to thousands of brain MRI scans and demonstrate that, after controlling for demographic and clinical covariates, lower PVS count and higher mean PVS diameter were significantly associated with a dose-response higher risk of developing dementia, and with accelerated brain atrophy.

Our MRI PVS markers required only a commonly acquired volumetric T1-weighted sequence, were computed in a fully-automated fashion, and showed excellent inter-scanner and test-retest reproducibility. These features may allow for our PVS markers to be readily implemented in clinical practice, as well as retrospective analyses of currently available brain MRI data. As we showed in our clinical trial simulations, their use may reduce the cost and duration of clinical trials for dementia prevention and treatment by facilitating the identification and enrolment of participants with increased risk of cognitive decline.

1. A method for magnetic resonance imaging comprising:
a) performing an MRI scan to produce a three-dimensional T1-weighted image;
b) generating from the three-dimensional T1-weighted image a white matter mask;
c) generating from the white matter mask a vesselness map using a multiscale vessel enhancement filtering technique;
d) automatically estimating a threshold on the vesselness map to define vascular structures, wherein the threshold is a vesselness value corresponding to a predetermined percentile of the total number of non-zero voxels; and
e) automatically generating a segmentation mask of vascular and perivascular structures by
i) using the estimated threshold to retain and binarize voxels with vesselness value above the estimated threshold,
ii) using anatomical landmarks to exclude white matter areas where false positive vessel-like structures are commonly found, and
iii) using morphological features of the retained voxels to further exclude voxels that represent background noise and are not consistent with vascular and perivascular structures.

2. The method of claim 1 wherein the predetermined percentile is in the range from 50 to 99.

3. The method of claim 1 wherein the predetermined percentile is in the range from 75 to 90.

4. The method of claim 1 wherein the predetermined percentile is in the range from 84 to 86.

5. The method of claim 1 wherein the predetermined percentile is 85.

6. The method of claim 1 wherein step (b) is performed using a FreeSurfer recon-all pipeline.

7. The method of claim 1 wherein step (c) is performed by applying the Frangi filter with default parameters.

8. The method of claim 1 further comprising generating from the three-dimensional T1-weighted image a basal ganglia mask.

9. The method of claim 8 wherein the vesselness map is generated from the white matter mask and the basal ganglia mask.

10. The method of claim 8 further comprising using the anatomical landmarks to exclude basal ganglia areas where false positive vessel-like structures are commonly found.
